(19) United States
(12) Patent Application Publication
(10) Pub. No.: US 2026/0198024 A1
(43) Pub. Date: Jul. 9, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takeshi SUWA, Kawasaki Kanagawa (JP); Tomoko MATSUDAI, Shibuya Tokyo (JP); Yoko IWAKAJI, Meguro Tokyo (JP)

(21) Appl. No.: 19/274,420

(22) Filed: Jul. 18, 2025

(30) Foreign Application Priority Data
Jan. 9, 2025 (JP) 2025-003640

(51) Int. Cl. H10D 12/00; H10D 62/10

(52) U.S. Cl. CPC H10D 12/415; H10D 12/481; H10D 62/107

(57) ABSTRACT

A semiconductor device includes first and second electrodes, and a conductive part. The second electrode is separated from the first electrode in a first direction. The semiconductor layer is located in a cell region of the device and in a termination region of the device. The semiconductor layer includes a first surface, and a second surface. The semiconductor layer includes first to third semiconductor regions, a plurality of guard ring regions, and a first intermediate region. The plurality of guard ring regions is located in the termination region. The plurality of guard ring regions surrounds the cell region. The first intermediate region is located inside the first semiconductor region in the termination region. The first intermediate region surrounds the cell region. The first intermediate region is positioned between the first surface and a center of the semiconductor layer in the first direction.

### CROSS-REFERENCE TO RELATED APPLICATIONS

This application is based upon and claims the benefit of priority from Japanese Patent Application No. 2025-003640, filed on Jan. 9, 2025; the entire contents of which are incorporated herein by reference.

### FIELD

Embodiments relate to a semiconductor device.

### BACKGROUND

A semiconductor device includes, for example, a termination region outside a cell region; and the cell region includes elements such as IGBTs (Insulated Gate Bipolar Transistors), MOSFETs (Metal-Oxide-Semiconductor Field-Effect Transistors), diodes, etc. It is desirable to increase the reliability of such a semiconductor device.

### BRIEF DESCRIPTION OF THE DRAWINGS

FIG. 1 is a schematic plan view illustrating a semiconductor device according to an embodiment;

FIG. 2 is a schematic plan view illustrating a semiconductor device according to an embodiment;

FIG. 3 is a schematic cross-sectional view illustrating a semiconductor device according to an embodiment;

FIG. 4 is a schematic cross-sectional view illustrating the semiconductor device according to the embodiment;

FIG. 5 is a schematic plan view illustrating the semiconductor device according to the embodiment;

FIG. 6 is a schematic graph illustrating snapback characteristics in termination regions of semiconductor devices;

FIG. 7 is a schematic graph illustrating a second-conductivity-type impurity concentration distribution along the Z-direction of the semiconductor layer according to the embodiment;

FIG. 8 is a schematic cross-sectional view illustrating another semiconductor device according to an embodiment;

FIG. 9 is a schematic cross-sectional view illustrating another semiconductor device according to an embodiment;

FIG. 10 is a schematic cross-sectional view illustrating another semiconductor device according to an embodiment;

FIG. 11 is a schematic cross-sectional view illustrating another semiconductor device according to an embodiment;

FIG. 12 is a schematic cross-sectional view illustrating another semiconductor device according to an embodiment;

FIG. 13 is a schematic cross-sectional view illustrating another semiconductor device according to an embodiment;

FIG. 14 is a schematic cross-sectional view illustrating another semiconductor device according to an embodiment;

FIG. 15 is a schematic cross-sectional view illustrating other semiconductor devices according to an embodiment; and

FIG. 16 is a schematic cross-sectional view illustrating other semiconductor devices according to an embodiment.

### DETAILED DESCRIPTION

A semiconductor device according to one embodiment, includes a first electrode, a second electrode, a semiconductor layer, and a conductive part. The second electrode is separated from the first electrode in a first direction. The semiconductor layer is located in a cell region of the device and in a termination region of the device. The termination region surrounds the cell region. The semiconductor layer is positioned between the first electrode and the second electrode in the cell region. The semiconductor layer includes a first surface proximate to the first electrode, and a second surface proximate to the second electrode. The semiconductor layer includes a first semiconductor region, a second semiconductor region, a third semiconductor region, a third semiconductor region, a plurality of guard ring regions, and a first intermediate region. The first semiconductor region is located in the cell region and the termination region. The first semiconductor region is of a first conductivity type. The second semiconductor region is located in the cell region between the first semiconductor region and the second electrode. The second semiconductor region is electrically connected to the second electrode. The second semiconductor region is of a second conductivity type. The third semiconductor region is located in the cell region between the second semiconductor region and the second electrode. The third semiconductor region is electrically connected to the second electrode. The third semiconductor region is of the first conductivity type. The plurality of guard ring regions is located in the termination region at the second surface side of the first semiconductor region. The plurality of guard ring regions surrounds the cell region. The plurality of guard ring regions is of the second conductivity type. The first intermediate region is located inside the first semiconductor region in the termination region. The first intermediate region surrounds the cell region. The first intermediate region is positioned between the first surface and a center of the semiconductor layer in the first direction. The first intermediate region is of the second conductivity type. The conductive part faces the second semiconductor region via an insulating layer.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

In the embodiments described below, each embodiment may be implemented by inverting the p-type (an example of the second conductivity type) and the n-type (an example of the first conductivity type) of each semiconductor region.

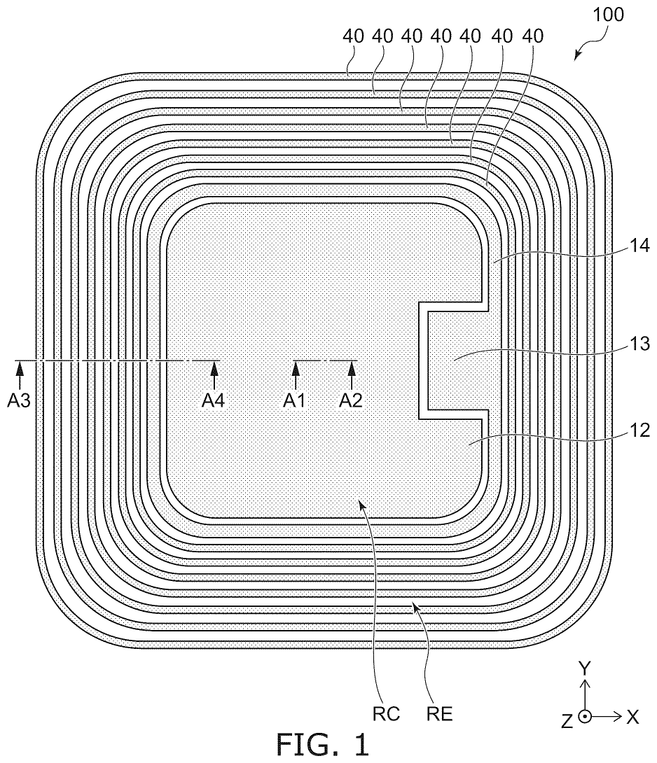

FIG. 1 is a schematic plan view illustrating a semiconductor device according to an embodiment.

As illustrated in FIG. 1, the semiconductor device 100 according to the embodiment includes a cell region RC, and a termination region RE surrounding the cell region RC. In the example, an IGBT is located in the cell region RC. Elements such as a MOSFET, a diode, etc., may be located in the cell region RC.

The semiconductor device 100 includes a first electrode 11 (e.g., a collector electrode) that will be described below, a second electrode 12 (e.g., an emitter electrode) illustrated in FIG. 1, a third electrode 13 (e.g., a gate electrode pad), and a wiring part 14 (e.g., a gate wiring part). The second electrode 12 is located in the cell region RC at the upper surface side of the semiconductor device 100.

The third electrode 13 and the wiring part 14 are arranged with the second electrode 12 in directions in the X-Y plane. The third electrode 13 and the wiring part 14 are separated from the second electrode 12 and insulated from the second electrode 12. The wiring part 14 surrounds the second electrode 12, is continuous with the third electrode 13, and is electrically connected to the third electrode 13.

The semiconductor device 100 also includes multiple electrodes 40 located in the termination region RE. The electrodes 40 are arranged with the second electrode 12 in directions in the X-Y plane. The electrodes 40 have ring shapes surrounding the second electrode 12, the third electrode 13, and the wiring part 14. The multiple electrodes 40 are separated from each other. The electrodes 40 are separated from the second electrode 12, the third electrode 13, and the wiring part 14, and are insulated from the second electrode 12, the third electrode 13, and the wiring part 14. For example, the potentials of the electrodes 40 are floating.

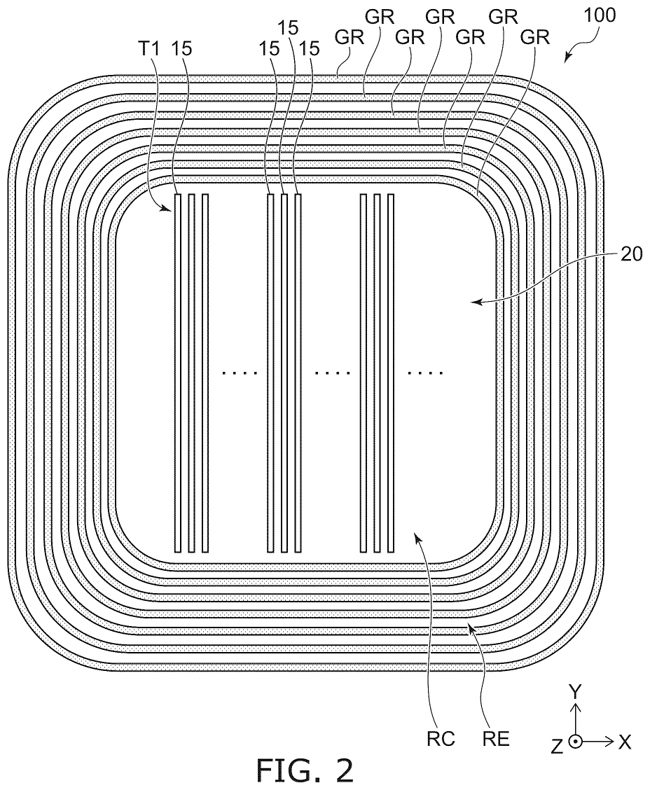

FIG. 2 is a schematic plan view illustrating a semiconductor device according to an embodiment.

FIG. 2 illustrates the layout of layers under the electrodes (the second electrode 12, the third electrode 13, and the electrode 40), the wiring parts, the insulating films, etc., located at the upper surface side of the semiconductor device 100, which are not illustrated. A guard ring region GR0 and the like that are described below also are not illustrated.

The semiconductor device 100 includes a semiconductor layer 20 and multiple conductive parts 15 (e.g., gate electrodes). The semiconductor layer 20 is located in the cell region RC and the termination region RE. In the example as described below, the conductive parts 15 are located inside trenches T1 formed in the semiconductor layer 20. In the cell region RC, the multiple conductive parts 15 are arranged in the X-direction; and each conductive part 15 extends in the Y-direction.

The semiconductor layer 20 includes multiple guard ring regions GR. The guard ring regions GR are located in the termination region RE at the surface of the semiconductor layer 20. The guard ring regions GR have ring shapes surrounding the cell region RC. The multiple guard ring regions GR are separated from each other.

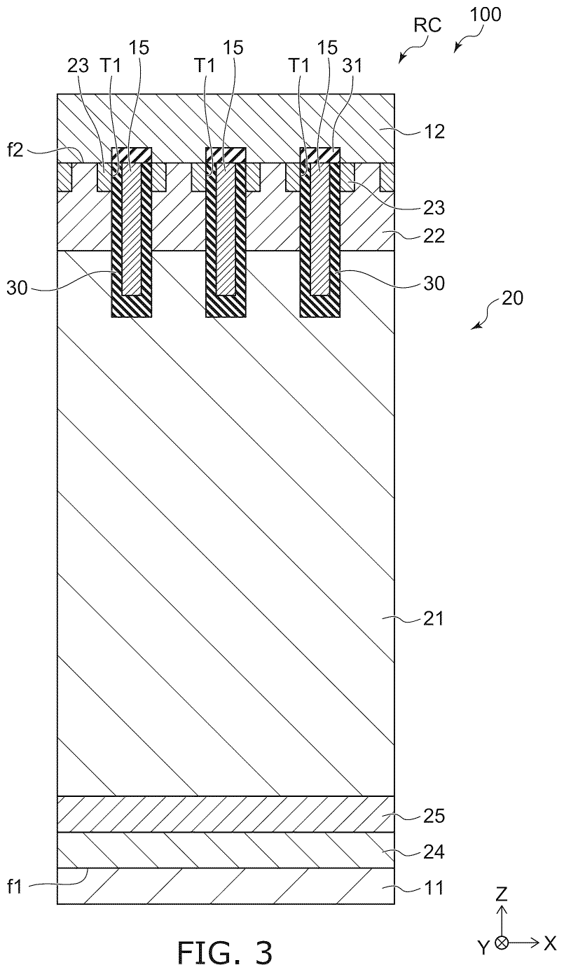

FIG. 3 is a schematic cross-sectional view illustrating a semiconductor device according to an embodiment.

FIG. 3 illustrates a cross section along line A1-A2 shown in FIG. 1, i.e., a cross section of the cell region RC.

As illustrated in FIG. 3, the second electrode 12 is separated from the first electrode 11 in a Z-direction. In the description of the embodiments, the direction from the first electrode 11 toward the second electrode 12 is referred to as the Z-direction (a first direction). For example, the Z-direction is the thickness direction of the semiconductor layer 20. In the description, the direction from the first electrode 11 toward the second electrode 12 is referred to as “up” or “above”, and the opposite direction is referred to as “down” or “below”. These directions are based on the relative positional relationship between the first electrode 11 and the second electrode 12, and are independent of the direction of gravity. The X-direction, the Y-direction, and the Z-direction are perpendicular to each other.

The semiconductor layer 20 is positioned between the first electrode 11 and the second electrode 12 in the cell region RC. The semiconductor layer 20 includes a first surface f1 (the lower surface) at the first electrode 11 side, and a second surface f2 (the upper surface) at the second electrode 12 side. The first surface f1 and the second surface f2 extend along the X-Y plane. The first electrode 11 contacts the first surface f1 and is electrically connected to the semiconductor layer 20. The second electrode 12 contacts the second surface f2 and is electrically connected to the semiconductor layer 20.

The semiconductor layer 20 includes a first semiconductor region 21 (e.g., a drift region), a second semiconductor region 22 (e.g., a base region), and a third semiconductor region 23 (e.g., a source region). The semiconductor layer 20 may further include a fourth semiconductor region 24 (e.g., a collector region) and a fifth semiconductor region 25 (e.g., a buffer region).

The fourth semiconductor region 24 is located on the first electrode 11. The fourth semiconductor region 24 contacts the first electrode 11. The fourth semiconductor region 24 is of a second conductivity type.

The fifth semiconductor region 25 is located on the fourth semiconductor region 24. The fifth semiconductor region 25 is of a first conductivity type.

The first semiconductor region 21 is located on the fifth semiconductor region 25. The first semiconductor region 21 is of the first conductivity type. The first-conductivity-type impurity concentration in the first semiconductor region 21 is less than the first-conductivity-type impurity concentration in the fifth semiconductor region 25.

The second semiconductor region 22 is located on the first semiconductor region 21 in the cell region RC. In other words, the second semiconductor region 22 is between the first semiconductor region 21 and the second electrode 12. The second semiconductor region 22 is of the second conductivity type.

The third semiconductor region 23 is located on a portion of the second semiconductor region 22 in the cell region RC. In other words, the third semiconductor region 23 is between the second semiconductor region 22 and the second electrode 12. The third semiconductor region 23 is of the first conductivity type.

The conductive part 15 faces the first semiconductor region 21, the second semiconductor region 22, and the third semiconductor region 23 via an insulating layer 30. In the example, the conductive part 15 and the insulating layer 30 are located inside the trench T1 formed in the semiconductor layer 20. The trench T1 extends from the second surface f2 to the first semiconductor region 21 in the Z-direction. The insulating layer 30 is located at the inner wall of the trench T1. The insulating layer 30 contacts the first semiconductor region 21, the second semiconductor region 22, and the third semiconductor region 23. The conductive part 15 is located at the inner side of the insulating layer 30 inside the trench T1, and is insulated from the semiconductor layer 20 by the insulating layer 30. The conductive part 15 is arranged with the first semiconductor region 21, the second semiconductor region 22, and the third semiconductor region 23 in the X-direction.

The second electrode 12 contacts the second and third semiconductor regions 22 and 23 and is electrically connected to the second and third semiconductor regions 22 and 23. The second-conductivity-type impurity concentration of a contact part of the second semiconductor region 22 that contacts the second electrode 12 may be greater than those of the other parts of the second semiconductor region 22. The second electrode 12 is insulated from the conductive part 15 by an insulating layer 31.

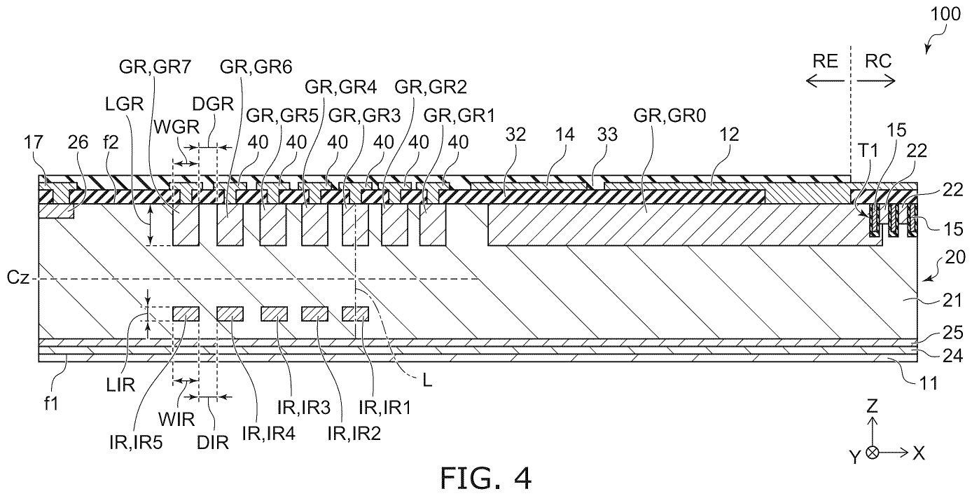

FIG. 4 is a schematic cross-sectional view illustrating the semiconductor device according to the embodiment.

FIG. 4 illustrates a cross section along line A3-A4 shown in FIG. 1, i.e., a cross section of the termination region RE and a portion of the cell region RC.

The first electrode 11, the fourth semiconductor region 24, the fifth semiconductor region 25, and the first semiconductor region 21 extend through the cell region RC and the termination region RE.

The guard ring regions GR are located on the first semiconductor region 21 at the second surface f2 side of the semiconductor layer 20. For example, the guard ring regions GR extend lower than the trenches T1 from the second surface f2. The guard ring regions GR are semiconductor regions of the second conductivity type. Portions of the first semiconductor region 21 are positioned between mutually-adjacent guard ring regions GR.

In the example, the multiple guard ring regions GR include guard ring regions GR0 to GR7. The guard ring region GR0, the guard ring region GR1, the guard ring region GR2, the guard ring region GR3, the guard ring region GR4, the guard ring region GR5, the guard ring region GR6, and the guard ring region GR7 are arranged in this order from the cell region RC side. For example, the potentials of the guard ring regions GR are in floating states. For example, the guard ring regions GR cause a depletion layer to spread in the termination region RE and suppress the electric field.

The guard ring region GR0 (an innermost guard ring region positioned furthest toward the cell region RC side among the guard ring regions GR) may contact, for example, the trench T1 and the second semiconductor region 22. The guard ring region GR0 “being located in the termination region RE and surrounding the cell region RC” may include the case where a portion of the guard ring region GR0 extends beyond the boundary between the cell region RC and the termination region RE and extends to the end part of the cell region RC.

The guard ring region GR0 extends below the second electrode 12 and the wiring part 14. The second electrode 12 contacts the top of the guard ring region GR0 and is electrically connected to the guard ring region GR0. The wiring part 14 is insulated from the semiconductor layer 20 by an insulating layer 32.

For example, the second-conductivity-type impurity concentrations in the multiple guard ring regions GR1 to GR7 are equal. The second-conductivity-type impurity concentration in the guard ring region GR0 may be greater than the second-conductivity-type impurity concentrations of the other guard ring regions GR1 to GR7.

The electrodes 40 are located respectively on the guard ring regions GR1 to GR7 in contact with the guard ring regions GR1 to GR7, and are electrically connected respectively to the guard ring regions GR1 to GR7.

The semiconductor layer 20 includes a semiconductor region 26 of the first conductivity type positioned at the outer end part of the termination region RE. The semiconductor region 26 is located on the first semiconductor region 21 and surrounds the cell region RC. The semiconductor region 26 is, for example, an EQPR (Equi-potential Ring). The first-conductivity-type impurity concentration in the semiconductor region 26 is greater than the first-conductivity-type impurity concentration in the first semiconductor region 21. An electrode 17 is located on the semiconductor region 26 in contact with the semiconductor region 26, and is electrically connected to the semiconductor region 26.

The electrode 40 and the electrode 17 are separated from the first semiconductor region 21 by the insulating layer 32 on the semiconductor layer 20. An insulating layer 33 (a protective film) is located on the second electrode 12, the wiring part 14, the electrode 40, the electrode 17, and the insulating layer 32 in the termination region RE.

The semiconductor layer 20 further includes an intermediate region IR of the second conductivity type. The intermediate region IR is located inside the first semiconductor region 21 in the termination region RE. For example, the intermediate region IR is surrounded with the first semiconductor region 21 vertically and laterally and contacts the first semiconductor region 21. The first semiconductor region 21 is located between mutually-adjacent intermediate regions IR.

The intermediate region IR is positioned at the lower part of the semiconductor layer 20. In other words, the intermediate region IR is positioned between the first surface f1 and a center Cz of the semiconductor layer 20 in the Z-direction. The center Cz is a position at half of the semiconductor layer 20 in the thickness direction, i.e., a position that is equidistant from the first and second surfaces f1 and f2 in the Z-direction. For example, the intermediate region IR is in an electrically floating state.

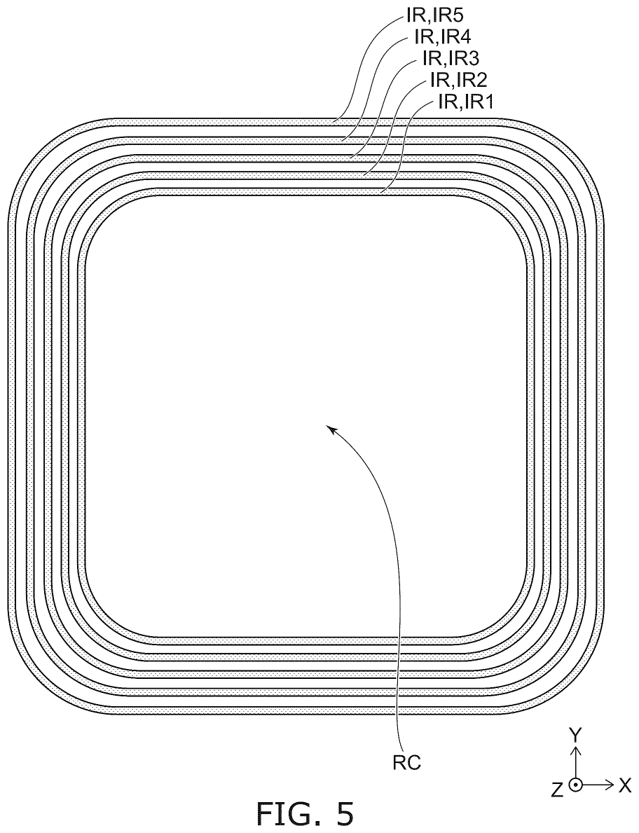

FIG. 5 is a schematic plan view illustrating the semiconductor device according to the embodiment.

FIG. 5 shows a planar shape of the intermediate region IR. For example, the intermediate region IR has a ring shape surrounding the cell region RC. In the example, multiple intermediate regions IR (intermediate regions IR1 to IR5) are included. The intermediate region IR1, the intermediate region IR2, the intermediate region IR3, the intermediate region IR4, and the intermediate region IR5 are arranged in this order from the cell region RC side. However, the number of the intermediate regions IR may be one, and is not particularly limited.

Examples of the materials of the components of the semiconductor device 100 will now be described.

The first semiconductor region 21, the second semiconductor region 22, the third semiconductor region 23, the fourth semiconductor region 24, the fifth semiconductor region 25, the semiconductor region 26, the guard ring region GR, and the intermediate region IR include silicon, silicon carbide, gallium nitride, or gallium arsenide as a semiconductor material. For example, the semiconductor layer 20 is a semiconductor substrate such as a silicon substrate, etc.

When silicon is used as the semiconductor material, arsenic, phosphorus, or antimony can be used as an n-type impurity. Boron can be used as a p-type impurity.

The conductive part 15 includes a conductive material such as polysilicon, etc. An impurity may be added to the conductive material.

The insulating layer 30, the insulating layer 31, and the insulating layer 32 include insulating materials such as silicon oxide, silicon nitride, etc.

The first electrode 11, the second electrode 12, the third electrode 13, the wiring part 14, the electrode 40, and the electrode 17 are conductive parts that include metals such as aluminum, copper, etc.

Operations of the semiconductor device 100 will now be described.

A voltage that is not less than a threshold is applied to the conductive part 15 in a state in which a voltage that is positive with respect to the second electrode 12 is applied to the first electrode 11. As a result, an inversion layer is formed in the second semiconductor region 22; and the state is switched to an on-state. For example, electrons flow from the second electrode 12 toward the first semiconductor region 21 via the third semiconductor region 23 and a channel. For example, holes flow from the first electrode 11 toward the first semiconductor region 21 via the fourth semiconductor region 24. Subsequently, when the voltage that is applied to the conductive part 15 drops below the threshold, the inversion layer in the second semiconductor region 22 disappears, and the state is switched to an off-state.

According to the embodiment as described above, the intermediate region IR of the second conductivity type is located in the semiconductor layer 20. The first intermediate region (one of the intermediate regions IR) is located inside the first semiconductor region 21 in the termination region RE, surrounds the cell region RC, and is positioned between the first surface f1 and the center Cz of the semiconductor layer 20 in the Z-direction. As a result, the reliability of the semiconductor device 100 can be increased.

For example, a depletion layer is formed at the periphery of the guard ring regions GR located at the upper part of the semiconductor layer 20 in the termination region RE. Here, for example, by locating the intermediate region IR in the lower part of the semiconductor layer 20 in the termination region RE, the depletion layer spreads to the periphery of the intermediate region IR. In other words, by including the intermediate region IR, the depletion layer can spread more in the region of the lower part of the semiconductor layer 20. As a result, the reliability in the termination region RE can be increased. For example, there are cases where impact ionization occurs at the periphery of the guard ring regions GR in the semiconductor layer 20. For example, when the intermediate region IR is included, compared to when the intermediate region IR is not included, impact ionization occurs further downward (at the first surface f1 side) as well. For example, the positions at which impact ionization occurs can be dispersed, the impact ionization at the upper surface side (the second surface f2 side) can be relaxed, and current concentration can be suppressed.

Impact ionization affects breakdown voltage and snapback characteristics.

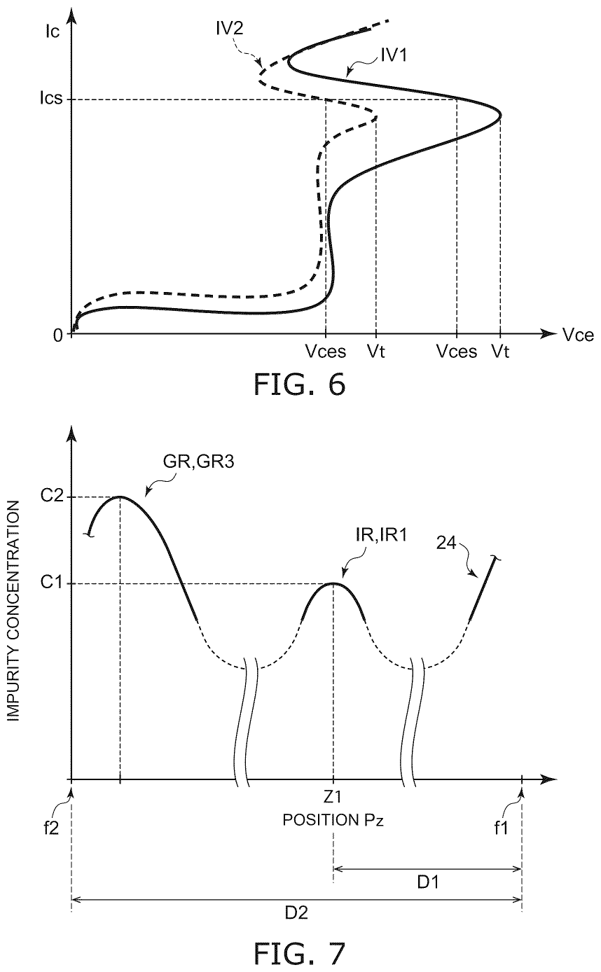

FIG. 6 is a schematic graph illustrating snapback characteristics in termination regions of semiconductor devices.

FIG. 6 illustrates the relationship between a voltage Vce (the voltage of the first electrode 11 with respect to the second electrode 12) and a current Ic in the first electrode 11 in the off-state. A characteristic IV1 illustrates a characteristic of the semiconductor device 100 according to the embodiment; and a characteristic IV2 illustrates a characteristic of a semiconductor device according to a reference example. Compared to the semiconductor device 100, the semiconductor device according to the reference example does not include the intermediate region IR.

As illustrated in FIG. 6, the value of the voltage Vce when the current Ic is a prescribed value Ics is taken as a breakover immunity Vces. The value Ics of the current Ic is the current value at which a negative resistance occurs and the slope of the graph becomes negative.

A trigger voltage Vt (the maximum value of the voltage Vce at which the slope of the graph switches from positive to negative) of the semiconductor device 100 according to the embodiment is greater than the trigger voltage Vt of the semiconductor device according to the reference example. The breakover immunity Vces of the semiconductor device 100 according to the embodiment is greater than the breakover immunity Vces of the semiconductor device according to the reference example. According to the embodiment, for example, the breakover immunity in the termination region RE can be improved. For example, current concentration in the termination region RE can be suppressed, and the reliability can be increased.

When the snapback characteristic is greatly unbalanced between the cell region RC and the termination region RE, it is considered that breakdown may occur easily due to current concentration in one of the cell region RC or the termination region RE; and the reliability may undesirably degrade. In contrast, for example, the intermediate region IR can change the snapback characteristic in the termination region RE. By including the intermediate region IR, the breakover immunity in the termination region RE can be improved. For example, degradation of the reliability due to the snapback characteristic being unbalanced between the cell region RC and the termination region RE can be suppressed.

In the example as described above, the semiconductor layer 20 includes the multiple intermediate regions IR. By using multiple intermediate regions IR, the p-n junctions with the first semiconductor region 21 are increased. The depletion layer can spread more in the region of the lower part of the semiconductor layer 20.

For example, the intermediate region IR faces at least one guard ring region GR in the Z-direction. In other words, at least a portion of one intermediate region IR and one guard ring region GR are arranged (overlap) in the Z-direction. By the intermediate region IR facing the guard ring region GR, for example, the depletion layer that is formed by the guard ring region GR spreads downward easily.

For example, each of the multiple intermediate regions IR faces one guard ring region GR. In other words, the number of the guard ring regions GR that overlap one intermediate region IR in the Z-direction is one. For example, the number of the intermediate regions IR that overlaps one guard ring region GR in the Z-direction is one.

As illustrated in FIG. 4, the first semiconductor region 21 is continuous between the intermediate region IR and the guard ring region GR that face each other. In other words, a p-type semiconductor region may not be located inside the first semiconductor region 21 between the intermediate region IR and the guard ring region GR facing each other to be separated from the intermediate region IR and the guard ring region GR.

The first semiconductor region 21 is continuous between the intermediate region IR and the fifth semiconductor region 25. In other words, a p-type semiconductor region may not be located inside the first semiconductor region 21 below the intermediate region IR to be separated from the intermediate region IR.

In the example of FIG. 4, the guard ring region GR7 that is furthest from the cell region RC among the multiple guard ring regions GR faces the intermediate region IR5 in the Z-direction. As a result, for example, the depletion layer spreads easily downward at the end of the depletion layer formed by the guard ring regions. For example, the depletion layer easily spreads to a wider range in the termination region RE. The intermediate region IR5 may be the intermediate region IR furthest from the cell region RC among the multiple intermediate regions IR.

The guard ring region GR0 is most proximate to the cell region RC among the multiple guard ring regions GR. As in the example of FIG. 4, the guard ring region GR0 (the innermost guard ring region) may not face the intermediate region IR in the Z-direction.

The guard ring region GR1 is second most proximate to the cell region RC among the multiple guard ring regions GR, is positioned adjacent to the guard ring region GR0, and surrounds the guard ring region GR0. For example, the guard ring region GR1 (the first inner guard ring region) may not face the intermediate region IR in the Z-direction.

The guard ring region GR2 is third most proximate to the cell region RC among the multiple guard ring regions GR, is positioned adjacent to the guard ring region GR1, and surrounds the guard ring region GR1. For example, the guard ring region GR2 (the second inner guard ring region) may not face the intermediate region IR in the Z-direction.

The first semiconductor region 21 is continuous between the fifth semiconductor region 25 and the guard ring regions GR (GR0, GR1, and GR2) that do not face the intermediate regions IR. In other words, a p-type semiconductor region is not located inside the first semiconductor region 21 between the guard ring region GR and the fifth semiconductor region 25 to be separated from the guard ring region GR. The guard ring region GR does not overlap the intermediate region IR in the Z-direction.

The electric field and/or current easily concentrate at the periphery of the guard ring regions GR (GR0, GR1, and GR2) proximate to the cell region RC; and there are cases where the breakdown voltage is low. For example, there are cases where the electric field and/or current easily concentrates at the periphery of the end part at the outer side (the side opposite to the cell region RC) of the guard ring region GR0 most proximate to the cell region RC. Here, there are cases where the breakdown voltage is changed by locating the intermediate region IR below the guard ring region GR. For example, there is a possibility that the current path may be limited by the intermediate region IR. In contrast, for example, by not locating the intermediate region IR at a position proximate to the cell region RC (in other words, by locating the intermediate region IR at a position separated from the cell region RC), the effects on the breakdown voltage and/or limiting of the current path at a position proximate to the cell region RC can be suppressed, and the reliability can be further increased.

In the example, the guard ring regions GR (GR3 to GR7) that face the intermediate regions IR are arranged consecutively within the multiple guard ring regions GR. In other words, there is no guard ring region GR between the guard ring regions GR3 and GR7 that does not face the intermediate region IR.

In the example of FIG. 4, the Z-direction positions of the multiple intermediate regions IR are the same. In other words, the multiple intermediate regions IR are positioned on the same X-Y plane.

Distances DGR between the adjacent guard ring regions GR may be different. For example, as illustrated in FIG. 4, the distances DGR may be set to increase away from the cell region RC. In other words, for example, the distance DGR between the guard ring region GR7 and the guard ring region GR6 is greater than the distance DGR between the guard ring region GR6 and the guard ring region GR5.

Distances DIR between the adjacent intermediate regions IR may be different. For example, as illustrated in FIG. 4, the distances DIR may be set to increase away from the cell region RC. In other words, for example, the distance DIR between the intermediate region IR5 and the intermediate region IR4 is greater than the distance DIR between the intermediate region IR4 and the intermediate region IR3. The distances DIR are not limited thereto; and the distances DIR between the adjacent intermediate regions IR may be constant or may be set to decrease away from the cell region RC. Or, the distances DIR may be selectively different.

For example, the distance DIR between adjacent intermediate regions corresponds to the distance DGR between the facing guard ring regions. For example, the distance DIR between the intermediate region IR5 and the intermediate region IR4 may be equal to the distance DGR between the guard ring region GR7 and the guard ring region GR6.

For example, a width WIR (the X-direction length) of the intermediate region IR corresponds to a width WGR (the X-direction length) of the facing guard ring region GR. For example, the width WIR of the intermediate region IR5 may be equal to the width WGR of the facing guard ring region GR7. Similarly, the width of each intermediate region IR may be equal to the width of the guard ring region GR facing each intermediate region IR.

The widths WIR of the multiple intermediate regions IR may be equal. The widths WGR of the multiple guard ring regions GR may be equal.

For example, a length LIR in the Z-direction of the intermediate region IR is less than a length LGR in the Z-direction of the guard ring region GR. For example, the Z-direction length of the intermediate region IR5 is less than the Z-direction length of the facing guard ring region GR7. Similarly, the Z-direction length of each intermediate region IR may be less than the Z-direction length of the guard ring region GR facing each intermediate region IR.

The Z-direction lengths of the multiple intermediate regions IR may be equal. The Z-direction lengths of the multiple guard ring regions GR may be equal.

FIG. 7 is a schematic graph illustrating a second-conductivity-type impurity concentration distribution along the Z-direction of the semiconductor layer according to the embodiment.

FIG. 7 illustrates the impurity concentration (atoms/cm³) at a position Pz. The position Pz is, for example, the distance from the upper surface (the second surface f2) along line L illustrated in FIG. 4.

The second-conductivity-type impurity concentration in the intermediate region IR is less than the second-conductivity-type impurity concentration in at least a portion of the guard ring region GR. More specifically, the intermediate region IR has a first peak C1 (a maximum value) in the second-conductivity-type impurity concentration distribution in the Z-direction. The guard ring region GR has a second peak C2 (a maximum value) in the second-conductivity-type impurity concentration distribution in the Z-direction. For example, the first peak C1 is lower than the second peak C2. Thus, by reducing the second-conductivity-type impurity concentration in the intermediate region IR, for example, the depletion layer spreads more easily in the lower part of the semiconductor layer 20. For example, the first peak C1 is not less than 0.01 times and not more than 0.8 times the second peak C2.

A distance D1 between the first surface f1 and the position (a first peak position Z1) in the Z-direction of the first peak C1 is, for example, not less than 1/20 times and not more than 1/10 times a thickness D2 of the semiconductor layer 20. Because the intermediate region IR is separated from the first surface f1, for example, interference of the intermediate region IR with the fourth and fifth semiconductor regions 24 and 25 can be suppressed.

In the example of FIG. 7, the peak concentration (the first peak C1) of the impurity in the intermediate region IR1 is less than the peak concentration (the second peak C2) of the impurity in the guard ring region GR3 facing the intermediate region IR1. Similarly, the peak concentration of the impurity in each intermediate region IR may be less than the peak concentration of the impurity of the guard ring region GR facing each intermediate region IR.

The second-conductivity-type impurity concentrations of the multiple intermediate regions IR may be equal. The second-conductivity-type impurity concentrations are not limited thereto; and the second-conductivity-type impurity concentration in the first intermediate region (one of the intermediate regions IR) may be different from the second-conductivity-type impurity concentration in the second intermediate region (another one of the intermediate regions IR).

For example, the second-conductivity-type impurity concentrations in the multiple intermediate regions IR may be set to increase away from the cell region RC. In other words, for example, the peak concentration of the impurity in the intermediate region IR5 is greater than the peak concentration of the impurity in the intermediate region IR4; and the peak concentration of the impurity in the intermediate region IR4 is greater than the peak concentration of the impurity in the intermediate region IR3. By spreading the depletion layer outward in the lower part of the semiconductor layer 20, for example, the breakdown voltage can be further increased.

Or, the second-conductivity-type impurity concentration of the intermediate region IR may be selectively different. In other words, for example, the second-conductivity-type impurity concentration in the first intermediate region may be equal to the second-conductivity-type impurity concentration in the second intermediate region and different from the second-conductivity-type impurity concentration in a third intermediate region (another one of the intermediate regions IR). More specifically, for example, the peak concentration of the impurity in the intermediate region IR5 is equal to the peak concentration of the impurity in the intermediate region IR3 and greater or less than the peak concentration of the impurity in the intermediate region IR4. By selectively modifying the impurity concentration, for example, the necessary breakdown voltage can be easily ensured. The second-conductivity-type impurity concentration in one of the intermediate regions IR may be greater than the second-conductivity-type impurity concentration in the guard ring region GR.

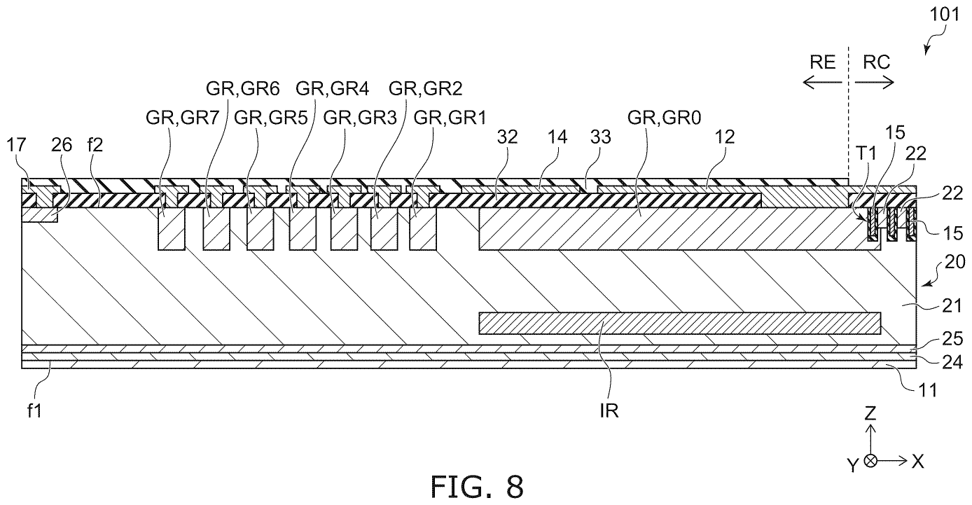

FIG. 8 is a schematic cross-sectional view illustrating another semiconductor device according to an embodiment.

In the semiconductor device 101, the intermediate region IR faces the guard ring region GR0. The guard ring regions GR1 to GR7 do not face the intermediate region IR. Thus, the intermediate region IR may be located below the guard ring region GR0 as well. There may be one intermediate region IR. Other than the above, the semiconductor device 101 may have a configuration similar to the configuration of the semiconductor device 100 (for example, the configuration illustrated in FIGS. 1 to 3).

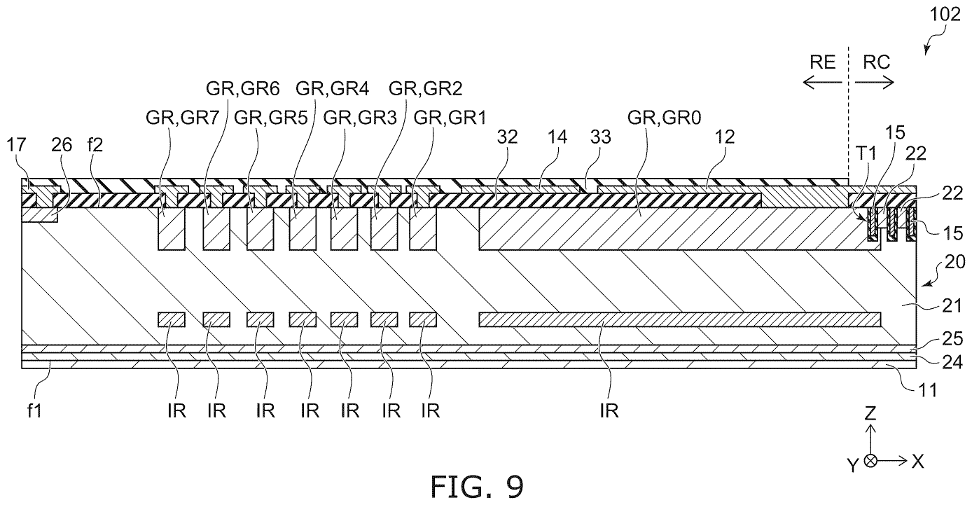

FIG. 9 is a schematic cross-sectional view illustrating another semiconductor device according to an embodiment.

In the semiconductor device 102, the intermediate regions IR respectively face the multiple guard ring regions GR. Thus, the intermediate regions IR may be located below the guard ring regions GR0, GR1, and GR2 as well. Other than the above, the semiconductor device 102 may have a configuration similar to the configurations of the semiconductor devices 100, 101 (for example, the configuration illustrated in FIGS. 1 to 3).

In the examples of FIGS. 8 and 9 as well, similarly to the semiconductor device described above, by including the intermediate region IR that faces the guard ring region GR, the depletion layer that is formed by the guard ring region GR can spread downward, and the reliability can be increased. For example, impact ionization can occur at the lower surface side as well, current concentration can be suppressed, and the breakover immunity can be improved.

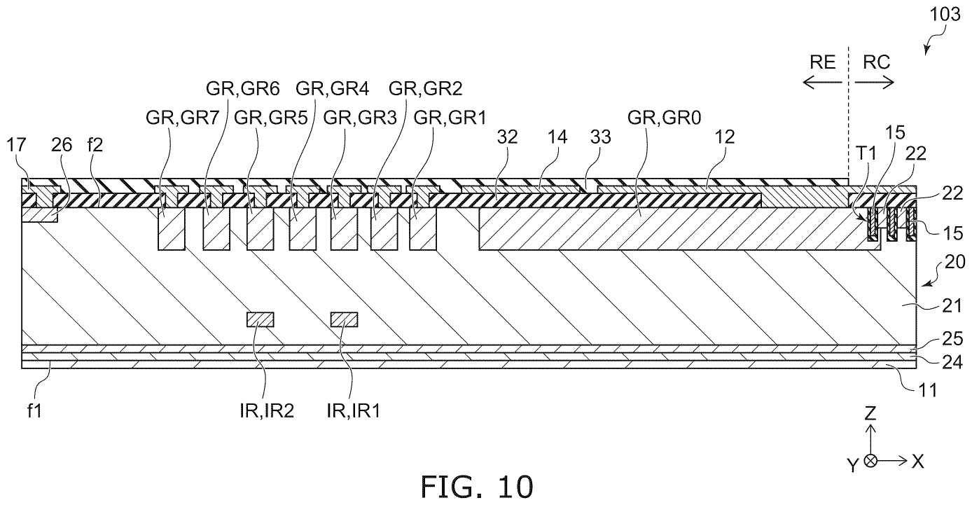

FIG. 10 is a schematic cross-sectional view illustrating another semiconductor device according to an embodiment.

In the semiconductor device 103, the multiple intermediate regions IR are selectively arranged for the multiple guard ring regions GR. In other words, the guard ring region GR3 faces the intermediate region IR1; the guard ring region GR4 does not face any of the intermediate regions IR; and the guard ring region GR5 faces the intermediate region IR2.

Thus, the multiple guard ring regions GR may include a first guard ring region facing the first intermediate region, a second guard ring region facing the second intermediate region, and a third guard ring region that is positioned between the first guard ring region and the second guard ring region and does not face an intermediate region. By selectively arranging the multiple intermediate regions IR, for example, the necessary breakdown voltage can be easily ensured. Other than the above, the semiconductor device 103 may have a configuration similar to the configurations of the semiconductor devices 100 to 102 (for example, the configuration illustrated in FIGS. 1 to 3).

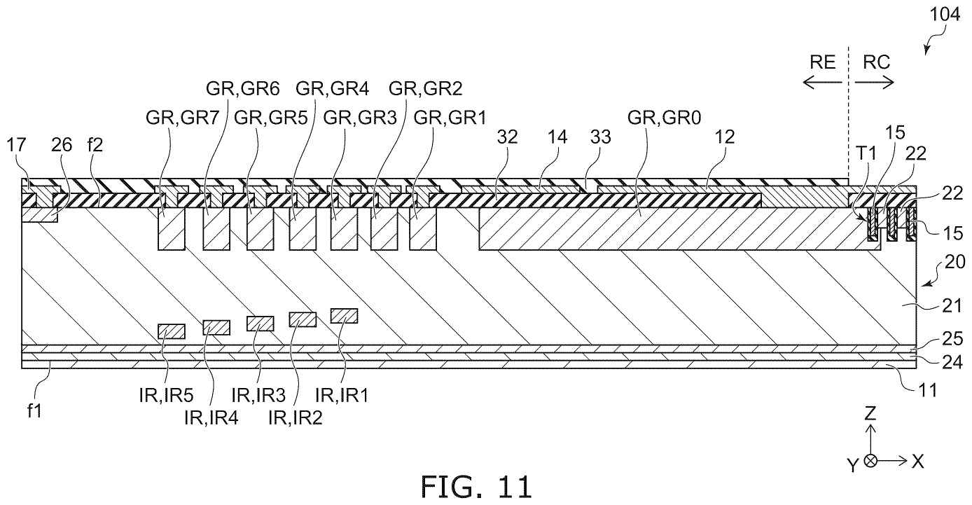

FIG. 11 is a schematic cross-sectional view illustrating another semiconductor device according to an embodiment.

The Z-direction positions of the intermediate regions IR may be different. In other words, the Z-direction position of the second intermediate region may be different from the Z-direction position of the first intermediate region.

For example, in the semiconductor device 104, the intermediate regions IR are arranged to approach the first surface f1 away from the cell region RC. More specifically, for example, the distance between the intermediate region IR5 and the first surface f1 is less than the distance between the intermediate region IR4 and the first surface f1. For example, the distance between the intermediate region IR4 and the first surface f1 is less than the distance between the intermediate region IR3 and the first surface f1. By spreading the depletion layer outward in the lower part of the semiconductor layer 20, for example, the breakdown voltage can be further increased. The arrangement is not limited to the arrangement described above; and the intermediate regions IR may be arranged to become distant to the first surface f1 away from the cell region RC.

Or, the distance between the intermediate region IR and the first surface f1 may be selectively different. In other words, for example, the distance between the first intermediate region and the first surface f1 may be equal to the distance between the second intermediate region and the first surface f1 and greater or less than the distance between the third intermediate region and the first surface f1. Other than the above, the semiconductor device 104 may have a configuration similar to the configurations of the semiconductor devices 100 to 103 (for example, the configuration illustrated in FIGS. 1 to 3).

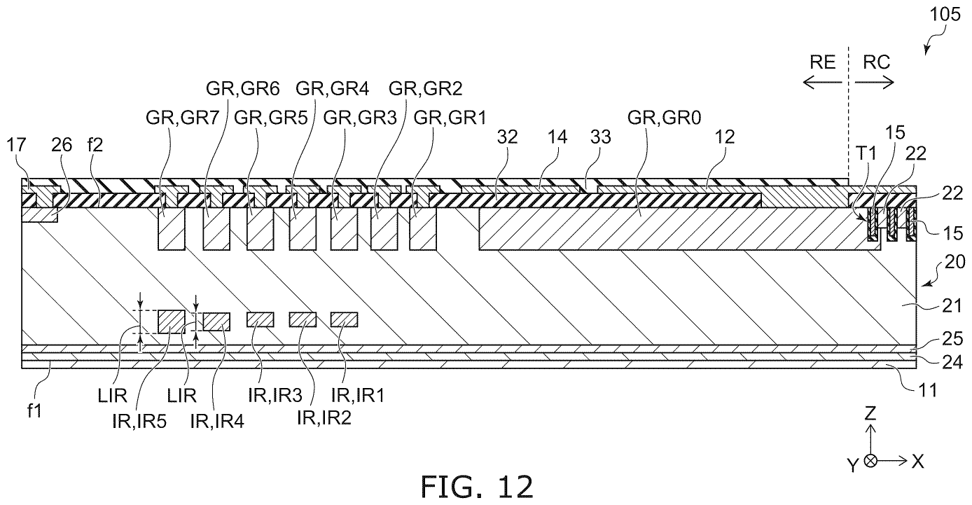

FIG. 12 is a schematic cross-sectional view illustrating another semiconductor device according to an embodiment.

The length LIR in the Z-direction of the intermediate region IR may be different. In other words, the Z-direction length in the second intermediate region may be different from the Z-direction length of the first intermediate region.

For example, in the semiconductor device 105, the lengths LIR in the Z-direction of the intermediate regions IR are set to increase away from the cell region RC. More specifically, for example, the length LIR in the Z-direction of the intermediate region IR5 is greater than the length LIR in the Z-direction of the intermediate region IR4. For example, the length LIR in the Z-direction of the intermediate region IR4 is greater than the length LIR in the Z-direction of the intermediate region IR3. The arrangement is not limited to the arrangement described above; and the lengths LIR in the Z-direction of the intermediate regions IR may be set to decrease away from the cell region RC.

Or, the lengths LIR in the Z-direction of the intermediate regions IR may be selectively different. In other words, for example, the length LIR in the Z-direction of the first intermediate region may be equal to the length LIR in the Z-direction of the second intermediate region and greater or less than the length LIR in the Z-direction of the third intermediate region. Other than the above, the semiconductor device 105 may have a configuration similar to the configurations of the semiconductor devices 100 to 104 (for example, the configuration illustrated in FIGS. 1 to 3).

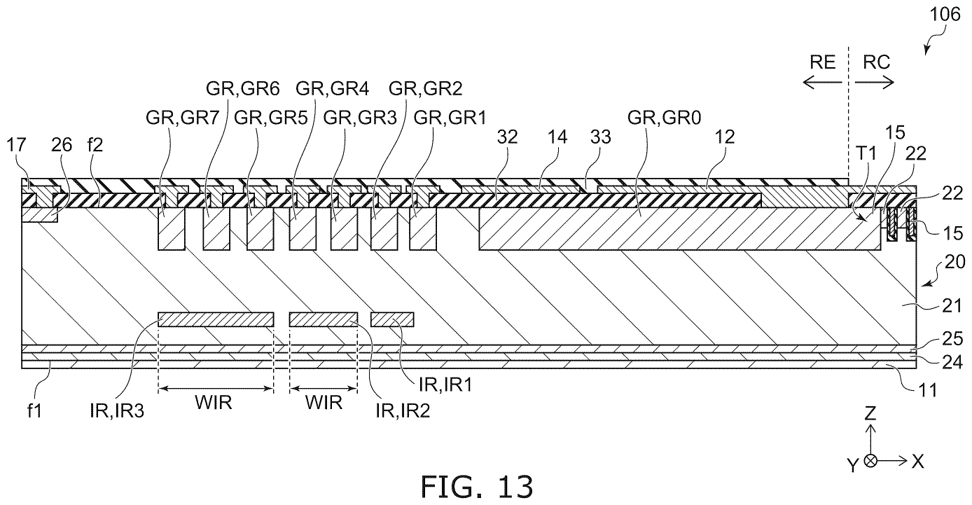

FIG. 13 is a schematic cross-sectional view illustrating another semiconductor device according to an embodiment.

In the semiconductor device 106, each of the multiple intermediate regions IR faces two or more of the multiple guard ring regions GR.

The widths WIR of the intermediate regions IR may be different. The Z-direction position of the second intermediate region may be different from the Z-direction position of the first intermediate region.

For example, in the semiconductor device 105, the widths WIR of the intermediate regions IR are set to increase away from the cell region RC. More specifically, for example, the width WIR of the intermediate region IR3 is greater than the width WIR of the intermediate region IR2. For example, the width WIR of the intermediate region IR2 is greater than the width WIR of the intermediate region IR1. Other than the above, the semiconductor device 106 may have a configuration similar to the configurations of the semiconductor devices 100 to 105 (for example, the configuration illustrated in FIGS. 1 to 3).

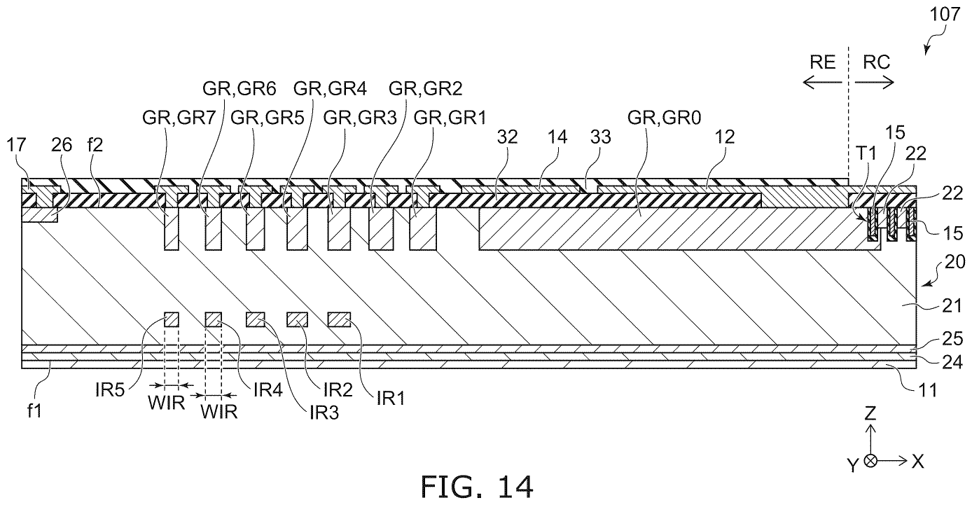

FIG. 14 is a schematic cross-sectional view illustrating another semiconductor device according to an embodiment.

In the semiconductor device 107, the widths WGR of the guard ring regions GR are set to decrease away from the cell region RC. For example, the width WGR of the guard ring region GR7 is less than the width WGR of the guard ring region GR6. For example, the width WGR of the guard ring region GR6 is less than the width WGR of the guard ring region GR5.

The width WIR of the intermediate region IR may correspond to the width WGR of the guard ring region GR. The widths WIR of the intermediate regions IR may be set to decrease away from the cell region RC. For example, the width WIR of the intermediate region IR5 is less than the width WIR of the intermediate region IR4. For example, the width WIR of the intermediate region IR4 is less than the width WIR of the intermediate region IR3.

The configuration is not limited thereto; and the widths WIR of the intermediate regions IR may be constant. For example, the widths WIR of the intermediate regions IR may be greater or less than the widths WGR of the guard ring regions GR facing the intermediate regions IR.

Or, the widths WIR of the intermediate regions IR may be selectively different. In other words, for example, the width WIR of the first intermediate region may be equal to the width WIR of the second intermediate region and greater or less than the width WIR of the third intermediate region. Other than the above, the semiconductor device 107 may have a configuration similar to the configurations of the semiconductor devices 100 to 106 (for example, the configuration illustrated in FIGS. 1 to 3).

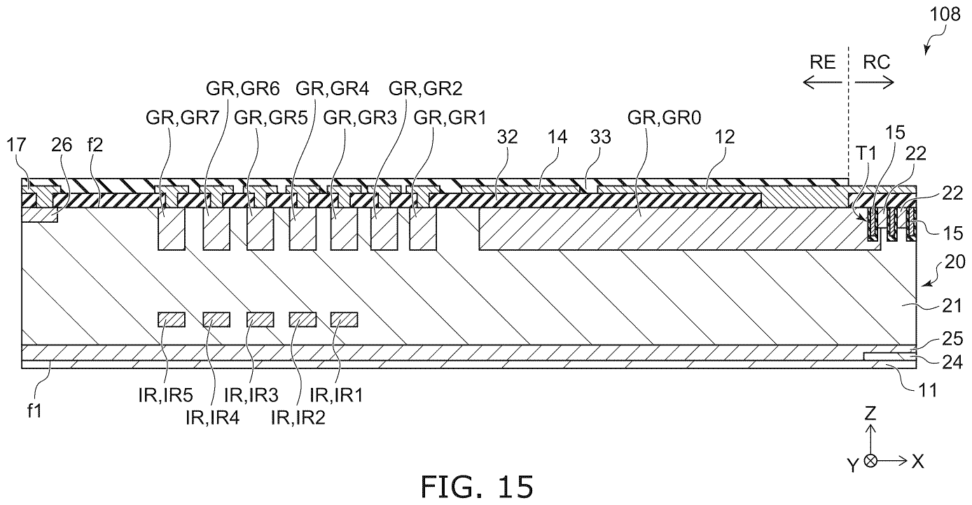

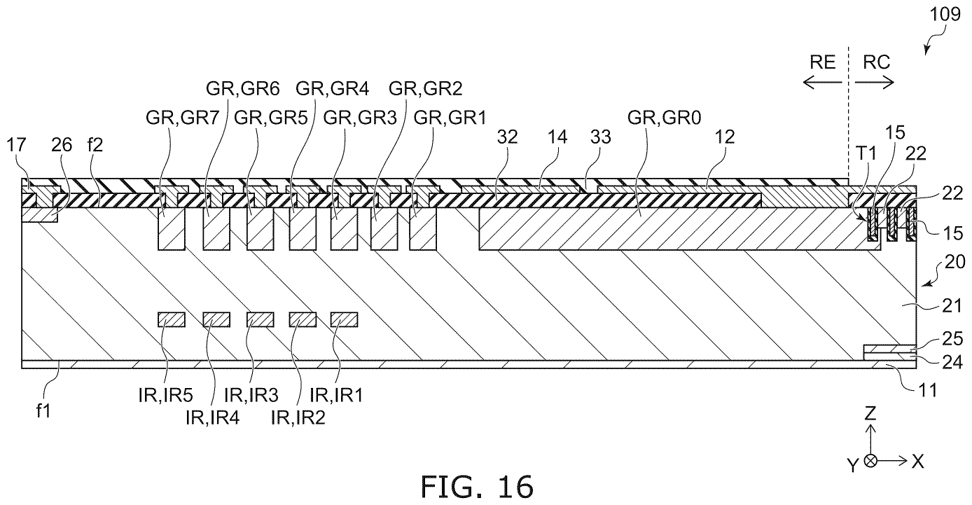

FIGS. 15 and 16 are schematic cross-sectional views illustrating other semiconductor devices according to embodiments.

In a semiconductor device 108 illustrated in FIG. 15, the fourth semiconductor region 24 is omitted from the termination region RE. In the termination region RE of the semiconductor device 108, the fifth semiconductor region 25 is located on the first electrode 11. Other than the above, the semiconductor device 108 may have a configuration similar to the configurations of the semiconductor devices 100 to 107 (for example, the configuration illustrated in FIGS. 1 to 3).

In a semiconductor device 109 illustrated in FIG. 16, the fourth semiconductor region 24 and the fifth semiconductor region 25 are omitted from the termination region RE. In the termination region RE of the semiconductor device 109, the first semiconductor region 21 is located on the first electrode 11.

Thus, the fourth semiconductor region 24 and the fifth semiconductor region 25 may be omitted as appropriate from the termination region RE. Also, for example, a vertical MOSFET or reverse-conducting IGBT may be configured by appropriately omitting the fourth semiconductor region 24 from the cell region RC. Other than the above, the semiconductor device 109 may have a configuration similar to the configurations of the semiconductor devices 100 to 108 (for example, the configuration illustrated in FIGS. 1 to 3).

Embodiments may include the following configurations.

### Configuration 1

A semiconductor device, comprising:
a first electrode;
a second electrode separated from the first electrode in a first direction;
a semiconductor layer located in a cell region of the device and in a termination region of the device, the termination region surrounding the cell region, the semiconductor layer being positioned between the first electrode and the second electrode in the cell region, the semiconductor layer including
   a first surface proximate to the first electrode,
   a second surface proximate to the second electrode,
   a first semiconductor region located in the cell region and the termination region, the first semiconductor region being of a first conductivity type,
   a second semiconductor region located in the cell region between the first semiconductor region and the second electrode, the second semiconductor region being electrically connected to the second electrode, the second semiconductor region being of a second conductivity type,
   a third semiconductor region located in the cell region between the second semiconductor region and the second electrode, the third semiconductor region being electrically connected to the second electrode, the third semiconductor region being of the first conductivity type,
   a plurality of guard ring regions located in the termination region at the second surface side of the first semiconductor region, the plurality of guard ring regions surrounding the cell region, the plurality of guard ring regions being of the second conductivity type, and
   a first intermediate region located inside the first semiconductor region in the termination region, the first intermediate region surrounding the cell region, the first intermediate region being positioned between the first surface and a center of the semiconductor layer in the first direction, the first intermediate region being of the second conductivity type; and
a conductive part facing the second semiconductor region via an insulating layer.

### Configuration 2

The device according to Configuration 1, wherein
a second-conductivity-type impurity concentration of the first intermediate region is less than a second-conductivity-type impurity concentration of at least a portion of the guard ring region.

### Configuration 3

The device according to Configuration 1 or 2, wherein
the first intermediate region faces at least one of the plurality of guard ring regions in the first direction.

### Configuration 4

The device according to any one of Configurations 1 to 3 wherein
the semiconductor layer includes a plurality of intermediate regions including the first intermediate region, and
each of the plurality of intermediate regions is located inside the first semiconductor region in the termination region, surrounds the cell region, is positioned between the first surface and the center in the first direction, and is of the second conductivity type.

### Configuration 5

The device according to Configuration 4, wherein
a guard ring furthest from the cell region among the plurality of guard ring regions faces at least one of the plurality of intermediate regions in the first direction.

### Configuration 6

The device according to Configuration 4 or 5, wherein
the plurality of guard ring regions includes:
   an innermost guard ring region that is most proximate to the cell region among the plurality of guard ring regions; and
   a first inner guard ring region positioned adjacent to the innermost guard ring region among the plurality of guard ring regions,
the first inner guard ring region surrounds the innermost guard ring region, and
the first inner guard ring region does not face any of the plurality of intermediate regions in the first direction.

### Configuration 7

The device according to Configuration 6, wherein
the innermost guard ring region does not face any of the plurality of intermediate regions in the first direction.

### Configuration 8

The device according to Configuration 6 or 7, wherein
the plurality of guard ring regions include a second inner guard ring region positioned adjacent to the first inner guard ring region among the plurality of guard ring regions,
the second inner guard ring region surrounds the first inner guard ring region, and
the second inner guard ring region does not face any of the plurality of intermediate regions in the first direction.

### Configuration 9

The device according to any one of Configurations 1 to 8 wherein
the first intermediate region has a first peak in a second-conductivity-type impurity concentration distribution of the semiconductor layer in the first direction, and
a distance between the first surface and a first peak position of the first peak in the first direction is not less than 1/20 times and not more than 1/10 times a thickness of the semiconductor layer.

### Configuration 10

The device according to Configuration 9, wherein
the guard ring region has a second peak in the second-conductivity-type impurity concentration distribution in the first direction, and
the first peak is not less than 0.01 times and not more than 0.8 times the second peak in the impurity concentration distribution.

### Configuration 11

The device according to any one of Configurations 4 to 10, wherein
each of the plurality of intermediate regions faces one of the plurality of guard ring regions.

### Configuration 12

The device according to any one of Configurations 4 to 10, wherein
each of the plurality of intermediate regions faces two or more of the plurality of guard ring regions.

### Configuration 13

The device according to any one of Configurations 4 to 12, wherein
guard ring regions among the plurality of guard ring regions facing intermediate regions among the plurality of intermediate regions are consecutively arranged within the plurality of guard ring regions.

### Configuration 14

The device according to any one of Configurations 4 to 12, wherein
the plurality of intermediate regions further include a second intermediate region,
the plurality of guard ring regions include:
   a first guard ring region facing the first intermediate region;
   a second guard ring region facing the second intermediate region; and
   a third guard ring region positioned between the first guard ring region and the second guard ring region, and
the third guard ring region does not face any of the plurality of intermediate regions in the first direction.

### Configuration 15

The device according to any one of Configurations 4 to 14, wherein
the plurality of intermediate regions include a second intermediate region, and
a position in the first direction of the second intermediate region is different from a position in the first direction of the first intermediate region.

### Configuration 16

The device according to any one of Configurations 4 to 15, wherein
the plurality of intermediate regions are arranged to approach the first surface away from the cell region.

### Configuration 17

The device according to any one of Configurations 4 to 16, wherein
the plurality of intermediate regions include a second intermediate region, and
a second-conductivity-type impurity concentration in the second intermediate region is different from a second-conductivity-type impurity concentration in the first intermediate region.

### Configuration 18

The device according to any one of Configurations 4 to 17, wherein
second-conductivity-type impurity concentrations in the plurality of intermediate regions are set to increase away from the cell region.

### Configuration 19

The device according to any one of Configurations 4 to 18, wherein
distances between adjacent intermediate regions among the plurality of intermediate regions are set to increase away from the cell region.

### Configuration 20

The device according to any one of Configurations 1 to 19, wherein
the semiconductor layer includes a fourth semiconductor region located between the first semiconductor region and the first electrode, and
the fourth semiconductor region is of the second conductivity type.

According to embodiments, a semiconductor device can be provided in which the reliability can be increased.

According to embodiments above, the impurity concentration in each semiconductor region can be measured by, for example, SIMS (secondary ion mass spectrometry). The relative levels of the impurity concentrations between the semiconductor regions can be confirmed using, for example, a SCM (scanning capacitance microscope). When both an impurity that forms donors and an impurity that forms acceptors are included in one region, the impurity concentration level may be the net impurity concentration level after the impurities have canceled.

In this specification, being “electrically connected” includes not only the case of being connected in direct contact, but also the case of being connected via another conductive member, etc.

The “same” or “equal” includes not only exactly the same or equal, but also substantially the same or substantially equal. For example, the scope of “same” or “equal” includes cases including differences caused by manufacturing process fluctuation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first electrode;
a second electrode separated from the first electrode in a first direction;
a semiconductor layer located in a cell region of the device and in a termination region of the device, the termination region surrounding the cell region, the semiconductor layer being positioned between the first electrode and the second electrode in the cell region, the semiconductor layer including
a first surface proximate to the first electrode,
a second surface proximate to the second electrode,
a first semiconductor region located in the cell region and the termination region, the first semiconductor region being of a first conductivity type,
a second semiconductor region located in the cell region between the first semiconductor region and the second electrode, the second semiconductor region being electrically connected to the second electrode, the second semiconductor region being of a second conductivity type,
a third semiconductor region located in the cell region between the second semiconductor region and the second electrode, the third semiconductor region being electrically connected to the second electrode, the third semiconductor region being of the first conductivity type,
a plurality of guard ring regions located in the termination region at the second surface side of the first semiconductor region, the plurality of guard ring regions surrounding the cell region, the plurality of guard ring regions being of the second conductivity type, and
a first intermediate region located inside the first semiconductor region in the termination region, the first intermediate region surrounding the cell region, the first intermediate region being positioned between the first surface and a center of the semiconductor layer in the first direction, the first intermediate region being of the second conductivity type; and
a conductive part facing the second semiconductor region via an insulating layer.

2. The device according to claim 1, wherein
a second-conductivity-type impurity concentration of the first intermediate region is less than a second-conductivity-type impurity concentration of at least a portion of the guard ring region.

3. The device according to claim 2, wherein
the first intermediate region faces at least one of the plurality of guard ring regions in the first direction.

4. The device according to claim 3, wherein
the semiconductor layer includes a plurality of intermediate regions including the first intermediate region, and
each of the plurality of intermediate regions is located inside the first semiconductor region in the termination region, surrounds the cell region, is positioned between the first surface and the center in the first direction, and is of the second conductivity type.

5. The device according to claim 4, wherein
a guard ring furthest from the cell region among the plurality of guard ring regions faces at least one of the plurality of intermediate regions in the first direction.

6. The device according to claim 4, wherein
the plurality of guard ring regions includes:
an innermost guard ring region that is most proximate to the cell region among the plurality of guard ring regions; and
a first inner guard ring region positioned adjacent to the innermost guard ring region among the plurality of guard ring regions,
the first inner guard ring region surrounds the innermost guard ring region, and
the first inner guard ring region does not face any of the plurality of intermediate regions in the first direction.

7. The device according to claim 6, wherein
the innermost guard ring region does not face any of the plurality of intermediate regions in the first direction.

8. The device according to claim 7, wherein
the plurality of guard ring regions include a second inner guard ring region positioned adjacent to the first inner guard ring region among the plurality of guard ring regions,
the second inner guard ring region surrounds the first inner guard ring region, and
the second inner guard ring region does not face any of the plurality of intermediate regions in the first direction.

9. The device according to claim 1, wherein
the first intermediate region has a first peak in a second-conductivity-type impurity concentration distribution of the semiconductor layer in the first direction, and
a distance between the first surface and a first peak position of the first peak in the first direction is not less than 1/20 times and not more than 1/10 times a thickness of the semiconductor layer.

10. The device according to claim 9, wherein
the guard ring region has a second peak in the second-conductivity-type impurity concentration distribution in the first direction, and
the first peak is not less than 0.01 times and not more than 0.8 times the second peak in the impurity concentration distribution.

11. The device according to claim 4, wherein
each of the plurality of intermediate regions faces one of the plurality of guard ring regions.

12. The device according to claim 4, wherein
each of the plurality of intermediate regions faces two or more of the plurality of guard ring regions.

13. The device according to claim 4, wherein
guard ring regions among the plurality of guard ring regions facing intermediate regions among the plurality of intermediate regions are consecutively arranged within the plurality of guard ring regions.

14. The device according to claim 4, wherein
the plurality of intermediate regions further include a second intermediate region,
the plurality of guard ring regions include:
a first guard ring region facing the first intermediate region;
a second guard ring region facing the second intermediate region; and
a third guard ring region positioned between the first guard ring region and the second guard ring region, and
the third guard ring region does not face any of the plurality of intermediate regions in the first direction.

15. The device according to claim 4, wherein
the plurality of intermediate regions include a second intermediate region, and
a position in the first direction of the second intermediate region is different from a position in the first direction of the first intermediate region.

16. The device according to claim 4, wherein
the plurality of intermediate regions are arranged to approach the first surface away from the cell region.

17. The device according to claim 4, wherein
the plurality of intermediate regions include a second intermediate region, and
a second-conductivity-type impurity concentration in the second intermediate region is different from a second-conductivity-type impurity concentration in the first intermediate region.

18. The device according to claim 4, wherein
second-conductivity-type impurity concentrations in the plurality of intermediate regions are set to increase away from the cell region.

19. The device according to claim 4, wherein
distances between adjacent intermediate regions among the plurality of intermediate regions are set to increase away from the cell region.

20. The device according to claim 1, wherein
the semiconductor layer includes a fourth semiconductor region located between the first semiconductor region and the first electrode, and
the fourth semiconductor region is of the second conductivity type.
